(19) United States
(12) Patent Application Publication
(10) Pub. No.: US 2024/0178832 A1
(43) Pub. Date: May 30, 2024

(54) ADAPTIVE VOLTAGE SCALING SYSTEM FOR OUT OF CONTEXT FUNCTIONAL SAFETY SoC

(71) Applicant: Texas Instruments Incorporated, Dallas, TX (US)

(72) Inventors: Venkateswar Reddy Kowkutla, Allen, TX (US); Chunhua Hu, Plano, TX (US); Erkan Bilhan, Dallas, TX (US); Sumant Dinkar Kale, Allen, TX (US)

(21) Appl. No.: 18/432,430

(22) Filed: Feb. 5, 2024

Related U.S. Application Data
(63) Continuation of application No. 16/912,057, filed on Jun. 25, 2020, now Pat. No. 11,923,836.
Application No. 16/912,057 is a continuation of application No. 15/393,513, filed on Dec. 29, 2016, now Pat. No. 10,734,993.

(51) Int. Cl. H03K 17/22; G05B 19/042; G06F 1/24; G06F 1/3296; H03K 17/30

(52) U.S. Cl. CPC H03K 17/22; G05B 19/042; G06F 1/24; G06F 1/3296; G05B 2219/21119; H03K 17/30

(57) ABSTRACT

Systems and methods are provided for voltage monitoring and reset sequencing. One such system includes a voltage detector including multiple voltage level detectors to output multiple power OK signals, respectively; a trim adjustment circuit to output multiple trim values to the multiple voltage level detectors, respectively; and a sequencer circuit coupled to the trim adjustment circuit and the voltage detector. In response to receiving the power OK signals from the multiple voltage level detectors, the sequencer circuit controls output of a reset signal to a target voltage domain.

### CROSS-REFERENCE TO RELATED APPLICATIONS

This application is a divisional of U.S. Non-Provisional patent application Ser. No. 16/912,057, filed Jun. 25, 2020, which is a continuation of U.S. Non-Provisional patent application Ser. No. 15/393,513, filed Dec. 29, 2016, both of which are incorporated by reference herein in their entireties.

### TECHNICAL FIELD OF THE INVENTION

The technical field of this invention is reset signal generation.

### BACKGROUND OF THE INVENTION

A functional safety system often requires implementing voltage detectors and supervisory functions for a complex System on a Chip (SoC) in a larger system. Implementing those functions outside of the SoC not only increases the overall system cost, it also lacks the critical features to achieve high level functional safety standard specified by ISO 2626 and IEC 61508.

### SUMMARY OF THE INVENTION

In order to design a complex SoC to achieve out of context functional safety features, embedded circuitry is required to generate an internal system reset with built in redundancy. Furthermore, the SoC also needs to comprehend the impact of external reset signals to make sure the device can enter a safe state when a fault occurs.

A fully integrated method is shown for generating a power on Reset on an SoC. Continuous voltage monitoring with integrated supervisory functions and reset sequencing is implemented, with redundant, multi stage voltage monitoring.

The optimum operating voltage of a complex SoC may be influenced by process variations. The voltages may be dynamically adjusted for optimal performance.

### BRIEF DESCRIPTION OF THE DRAWINGS

These and other aspects of this invention are illustrated in the drawings, in which:

FIG. 1 shows a high level diagram of the reset circuit;

FIG. 2 is a flow chart of the reset function;

FIG. 3 shows an implementation of the power OK masking circuitry; and

FIG. 4 shows a flow chart of the steps involved in the adaptive voltage scaling.

### DETAILED DESCRIPTION OF PREFERRED EMBODIMENTS

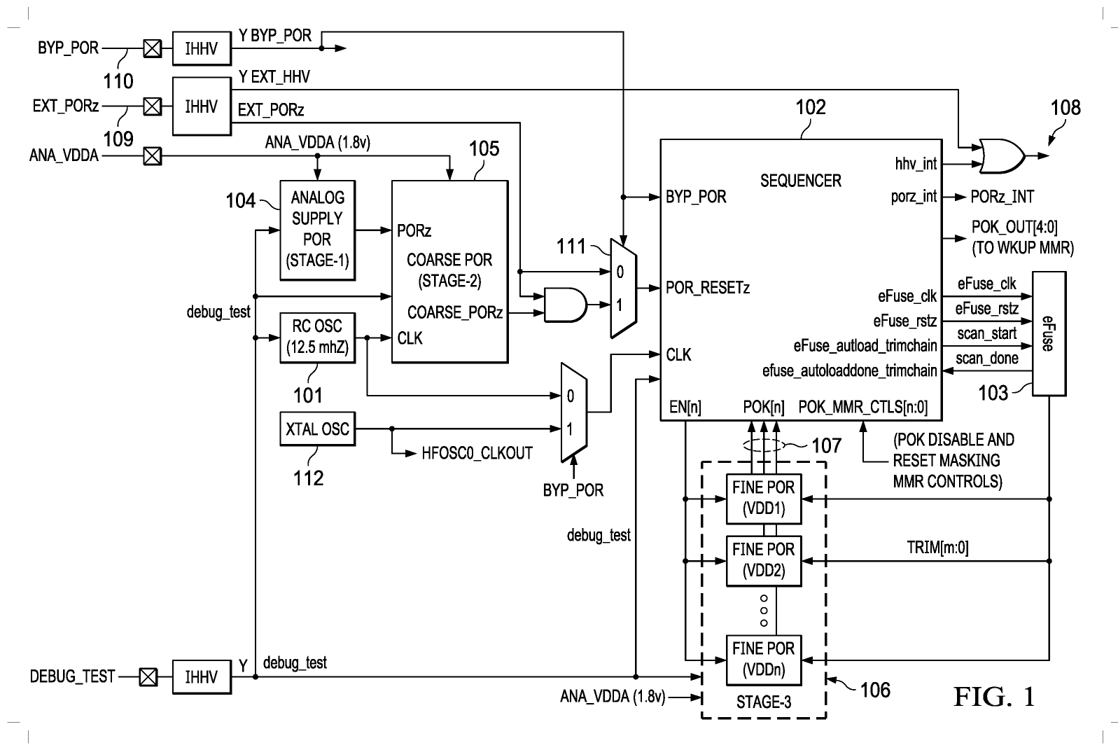

A fully integrated power on reset generation circuitry which can provide continuous voltage monitoring and reset sequencing is shown in FIG. 1. It incorporates control features such as redundancy and diagnostic capabilities which are critical to implement the functional safety feature.

The apparatus includes internal oscillators, a plurality of voltage detection stages and a power on reset (PoR) sequencer.

The internal RC oscillator 101 and crystal oscillator 112 are used to generate the clocks required by the power on reset (PoR) sequencer 102 and eFuse module 103. The outputs of voltage monitors 104, 105 and 106 are passed through deglitching circuits to filter out false signals such as glitches and noise from the analog sensors.

The first stage voltage detection circuit 104 is an analog power supply level detector—this is to ensure that the voltage has reached a threshold level at which analog circuits can safely and reliably operate. The second stage voltage detection circuit 105 is a coarse level detector on analog voltage rails and some critical digital voltage rails, which are required for fine tuning analog sensors for process and temperature variations. The third stage voltage detection circuit 106 is a plurality of more accurate level detectors, which ensures that all voltage rails are operating within specified limits. The circuits implemented in first and second stage do not require any trim values to fine tune the analog circuits for process and temperature variation compensations. The first stage voltage detection circuit 104 controls the reset to the second stage voltage detection circuit 105, and second stage controls the reset to the third stage voltage detection circuit 106. Final master reset signal 108 to the SoC will be a combined version of resets from all 3 stages. This ensures that the device will always receive a reset even if one of the stages is defective therefore providing the required redundancy needed for safety critical applications.

Once the voltage levels are valid, the second stage voltage detection circuit 105 releases reset to only a small portion of the device which enables the device to initiate the eFuse scanning. The eFuse block 103 contain analog trim values for the voltage detection circuits implemented in the third stage voltage detection circuit 106 for accurate voltage level monitoring. The third stage holds the reset to the designated voltage domains until it detects proper voltage levels on the rails.

After the eFuse scanning in eFuse block 103 is complete, the power on reset (PoR) sequencer 102 applies the trim values read out from the eFuse block 103 to the analog circuits for the voltage monitors in the third stage voltage detection circuit 106. The sequencer then enables the voltage monitors for accurate detection of voltage levels on the rails. The sequencer then waits for a power OK (POK) signal 107 response from each individual detector circuit. When all the voltage monitors indicate power OK on the rails, power on reset sequencer 102 waits for all IOs and clock oscillators in the device to stabilize and then de-asserts the reset signal 108 to the designated voltage domain.

Provision is made for external reset signals 109 and 110 that will override the internally generated resets when selected by selector 111.

All reset signals are properly level shifted to the destination voltage level with appropriate pull-up or pull-down functions. This is to ensure that if the source voltage dies, the reset signal is still at an appropriate level to put the destination voltage domain in the reset state.

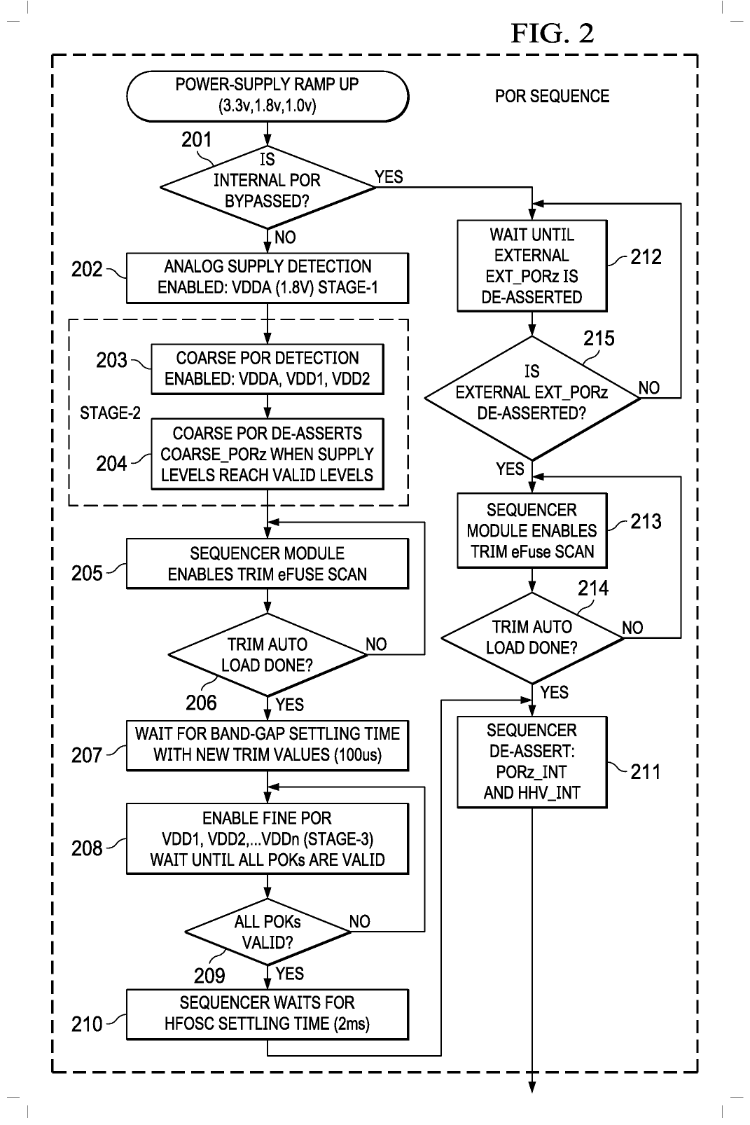

FIG. 2 shows the steps involved in the reset generation. Block 201 determines if the external PoR is asserted, and internal PoR bypassed. If not, analog power supply detection is enabled in block 202, followed by coarse PoR detection enabled in block 203. When power supply voltage levels reach valid levels, coarse PoR is deasserted in block 204. The sequencer module now enables the trim eFuse scan in block 205. When completion of the scan is determined, and the trim autoload is done, in block 206, a settling time is introduced in block 207, to wait for band-gap settling time with new trim values (100 us). After the settling time, the fine corrected power on reset signals are enabled in block 208. When all POK (Power OK) signals are valid as determined in block 209, an oscillator settling time is introduced, and the sequencer waits for HFOSC settling time (2 ms) in block 210, followed by the deassertion of the PoR signals by the sequencer in block 211.

If an external power on reset signal is detected in block 201, and internal PoR is bypassed, block 212 introduces a wait until the external power on reset signal is deasserted. Once the external power on reset signal is deasserted in block 215, the trim eFuse scan is enabled by the sequencer in block 213. Once trim auto load is completed in block 214, flow returns to block 211.

If an external power on reset signal is detected in block 201, block 212 introduces a wait until the external power on reset signal is deasserted. Once that is detected, the trim eFuse scan is enabled in block 213. Once trim auto load is completed, flow returns to block 211.

Adaptive Voltage Scaling (AVS) provides mechanism to dynamically adjust voltage settings for a given voltage domain for Process and Temperature variations. To improve performance certain processor/core voltage levels may be overdriven to higher voltages than nominal levels. In lower power modes, these same voltages may be lowered to reduce leakage. However, the voltage monitor's thresholds are set based on nominal voltage at power up stage. To accurately monitor new voltage levels after applying Adaptive Voltage Scaling, the voltage monitoring circuit's thresholds have to be reprogrammed to reflect the voltage changes. This invention provides an apparatus and method to allow re-configuration of the threshold settings which aligns with the new operating voltages for an out of context functional safety SoC.

To support Adaptive Voltage Scaling (AVS) and new operating voltages, the solution shown allows a safe sequence and circuitry to change the voltage monitor circuit thresholds to correspond to the new settings.

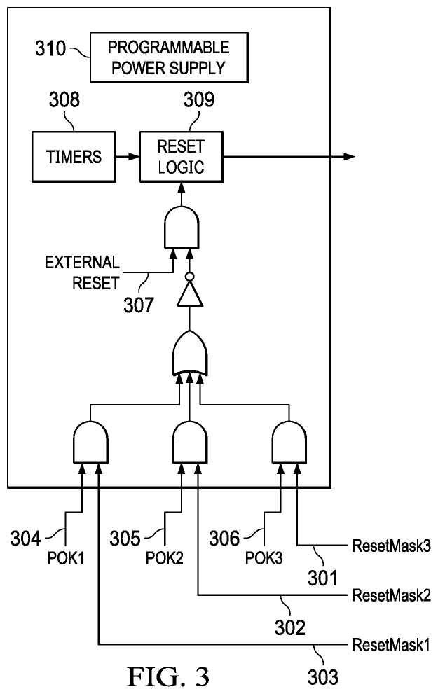

Prior to re-configuring the new threshold, the power OK signal coming out of that particular voltage monitor circuit must be masked as shown in FIG. 3. This ensures that any glitches coming out of voltage monitor are masked during reconfiguration of the threshold settings. Power OK signals 304, 305 and 306 are masked by reset masks 301, 302 and 303. The masked power OK signals are combined with external reset signal 307, and the final reset signal is generates by reset logic block 309. Timer block 308 is used by reset logic block 309 to implement settling times during the reconfiguration process as required.

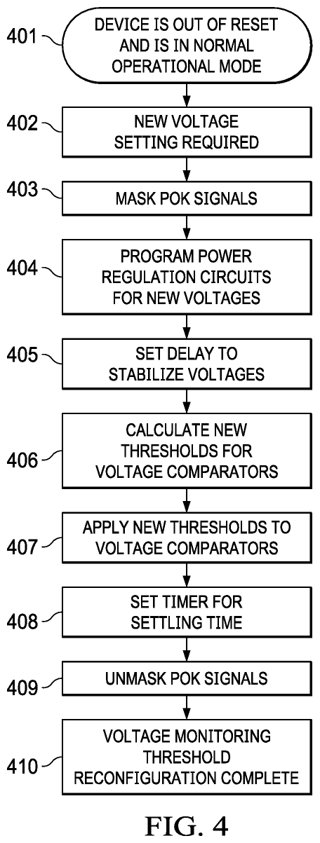

FIG. 4 demonstrates the steps employed to implement the threshold changes. The reconfiguration starts at block 401 with the device out of reset in the normal operating mode. When a new voltage setting is required in block 402, the power OK signals are masked in block 403. The power regulating circuits in programmable power supply 310 are programed to the new voltage requirements in block 404. A delay is set in block 405 to allow the new voltages to stabilize, and the new voltage thresholds for the voltage comparators is calculated in block 406, and are applied to the voltage comparators in block 407. A settling time is applied in block 408, by setting a timer, followed by unmasking of the power OK signals in block 409. As shown in block 410, this completes the voltage monitoring threshold reconfiguration process.

What is claimed is:

1. A method comprising:
receiving, from a set of voltage detectors, a set of power OK signals;
receiving, a set of mask signals;
providing a reset signal based on the set of power OK signals such that the reset signal is de-asserted based on each of the power OK signals being asserted;
masking the set of power OK signals based on the set of mask signals such that a response of the reset signal to the set of power OK signals is inhibited;
thereafter, updating a voltage threshold of the set of voltage detectors; and
thereafter, unmasking the set of power OK signals based on the set of mask signals.

2. The method of claim 1, wherein the providing of the reset signal includes:
applying an AND logic function to each power OK signal of the set of power OK signals and a respective mask signal of the set of mask signals to produce a set of intermediate signals; and
applying an OR logic function to the set of intermediate signals.

3. The method of claim 1, further comprising, after the masking the set of power OK signals, programming a set of power regulating circuits.

4. The method of claim 1, further comprising, based on a timer, causing the unmasking of the set of power OK signals to occur a settling time after the updating of the voltage threshold.

5. The method of claim 1, further comprising determining the voltage threshold of the set of voltage detectors.

6. The method of claim 1, further comprising, prior to the receiving of the set of power OK signals:
providing a set of trim values to the set of voltage detectors; and
thereafter, enabling the set of voltage detectors.

7. The method of claim 6, further comprising:
performing a coarse voltage level measurement of a power supply voltage; and
based on the coarse voltage level measurement, retrieving the set of trim values to provide to the set of voltage detectors.

8. The method of claim 7, further comprising:
performing a first voltage level measurement of the power supply voltage, wherein the performing of the coarse voltage level measurement is performed based on the first voltage level measurement.

9. A method comprising:
comparing each supply voltage of a set of supply voltages with a select one of a plurality of trim values;
generating a set of power OK signals based on the comparing operations;
providing a reset signal;
masking the set of power OK signals by applying the set of power OK signals and a set of mask signals to AND circuitry such that a response of the reset signal to the set of power OK signals is inhibited;
updating the trim values while the response of the reset signal is inhibited; and
unmasking the set of power OK signals.

10. The method of claim 9, wherein the updating of the trim values while the response of the reset signal is inhibited includes:
calculating new trim values based on a signal input to AND logic coupled to the AND circuitry; and
using the new trim values for subsequent comparing operations.

11. The method of claim 10, further comprising:
determining that new trim values are required; and
waiting a delay time period after determining that new trim values are required before calculating the new trim values.

12. The method of claim 11, further comprising:
waiting a settling time period before unmaking the power OK signals.

13. A system comprising:
a voltage detector including multiple voltage level detectors configured to output multiple power OK signals, respectively;
a trim adjustment circuit configured to output multiple trim values to the multiple voltage level detectors, respectively; and
a sequencer circuit coupled to the trim adjustment circuit and the voltage detector, wherein, in response to receiving the power OK signals from the multiple voltage level detectors, the sequencer circuit is configured to control output of a reset signal to a target voltage domain.

14. The system of claim 13, wherein the sequencer circuit is configured to de-assert the reset signal based on the multiple power OK signals being asserted.

15. The system of claim 14, wherein the sequencer circuit is configured to mask the power OK signals based on mask signals such that a response of the reset signal to the power OK signals is inhibited.

16. The system of claim 15, wherein the sequencer circuit is configured to, after masking the power OK signals, update a voltage threshold of the voltage detector.

17. The system of claim 16, wherein the sequencer circuit is configured to, after updating the voltage threshold, unmask the power OK signals based on mask signals.

18. The system of claim 13, wherein the voltage detector is configured to, in outputting the power OK signals, compare each supply voltage of a set of supply voltages with a select one of the multiple trim values received by the multiple voltage level detectors from the trim adjustment circuit, and output the power OK signals based on the comparing operations.

19. The system of claim 18, wherein the system is configured to:
provide a reset signal;
mask the power OK signals by applying the power OK signals and mask signals to AND logic circuitry such that a response of the reset signal to the power OK signals is inhibited;
update the trim values while the response of the reset signal is inhibited; and
unmask the power OK signals.
